(19) United States
(12) Patent Application Publication
(10) Pub. No.: US 2010/0006333 A1
(43) Pub. Date: Jan. 14, 2010

(54) Wiring substrate and method of manufacturing the same

(75) Inventor: Nobuhiko Ishizuka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/458,225

(22) Filed: Jul. 6, 2009

(30) Foreign Application Priority Data
Jul. 14, 2008 (JP) 183209/2008

(51) Int. Cl. H05K 1/11; G01R 31/28; H01R 9/00

(52) U.S. Cl. 174/261; 29/593; 29/842

(57) ABSTRACT

Provided is a wiring substrate which enables wiring density to be increased and enables transmission speed of signals to be adjusted without making a design change of wirings. A wiring substrate 100 is provided with a first terminal 110, a second terminal 120, a first wiring 112 and a second wiring 114. The first wiring 112 is such that one end thereof is connected to the first terminal 110, and is formed on the wiring substrate 100. The second wiring 114 is such that one end thereof is connected to the second terminal 120, and is formed on the wiring substrate 100. One end of each of a plurality of third wirings formed on the wiring substrate 100 is connected to the other end of the first wiring 112, and one end of each of a plurality of fourth wirings formed on the wiring substrate 100 is connected to the other end of the second wiring 114. The other end of at least one third wiring and the other end of at least fourth wiring are connected together.

### BACKGROUND OF THE INVENTION

1. Field of the Invention

The present invention relates to a wiring substrate which enables wiring density to be increased and enables the transmission speed of signals to be adjusted without making a design change of wirings and a method of manufacturing the wiring substrate.

2. Description of the Related Art

In a semiconductor chip, in some cases it is necessary to make the transmission speeds of a plurality of signals equal to each other. In such cases, in designing a semiconductor chip, a wiring substrate, a mother board and the like, the wiring length is made equal, whereby a difference in the transmission speed of signals is prevented from occurring. However, even when such designing is performed, differences may sometimes occur in the transmission speed of signals when products are actually made.

The following technique is disclosed in Japanese Patent Laid-Open No. 2005-322814. That is, for a wiring through which a signal propagates faster than a standard transmission speed, the capacitance is increased by connecting a gold wire to a pattern for adjustment provided in the vicinity of the wiring. Conversely, for a wiring through which a signal propagates slower than a standard transmission speed, in order to reduce the inductance a gold wire is connected via a pattern for adjustment provided in the vicinity of the wiring so that the wiring provides a parallel circuit.

However, with the technique described in Japanese Patent Laid-Open No. 2005-322814, it is necessary to provide a pattern for adjustment to connect a gold wire to a wiring. The wiring to which a gold wire is to be connected requires a bonding region (a pad) with a width larger than a usual signal wiring and, therefore, it is impossible to increase wiring density with the technique described in Japanese Patent Laid-Open No. 2005-322814. As described above, it has been difficult to make quite sure that increasing wiring density and ensuring that the transmission speed of signals can be adjusted without a design change of wirings are compatible.

### SUMMARY

The present invention provides a wiring substrate which is provided with a first terminal, a second terminal, a first wiring one end of which is connected to the first terminal and which is formed on the wiring substrate, and a second wiring one end of which is connected to the second terminal and which is formed on the wiring substrate. In this wiring substrate, one end of each of a plurality of third wirings formed on the wiring substrate is connected to the other end of the first wiring, one end of each of a plurality of fourth wirings formed on the wiring substrate is connected to the other end of the second wiring, and the other end of at least one third wiring and the other end of at least one fourth wiring are connected together.

According to this wiring substrate, there are provided a plurality of third wirings and fourth wirings which can be a path of signals from the first wiring to the second wiring. For this reason, it is possible to change the length of the path of signals from the first wiring to the second wiring by changing the third wirings and fourth wirings ends of both of which on the other side are connected together. Therefore, it is possible to adjust the transmission speed of signals without making a design change of wirings. Also, it is possible to increase wiring density because it is unnecessary to provide a pattern for gold wire connection at a midpoint in a wiring.

The present invention provides an wiring substrate which is provided with a first terminal, a second terminal, a first wiring which connects the first terminal and the second terminal together and is formed on the wiring substrate, a fifth wiring one end of which is connected to the second terminal or the first wiring and which is formed on the wiring substrate, and a plurality of sixth wirings one end of each of which is connected to the other end of the fifth wiring and the other end of each of which extends to an edge of the wiring substrate.

According to this wiring substrate, it is possible to select the wiring capacity of a wiring linked to the first wiring between a case where a fifth wiring and a plurality of sixth wirings are not decoupled and a case where the fifth wiring and the plurality of sixth wirings are decoupled at least at one point. Therefore, it is possible to adjust the transmission speed of signals without making a design change of wirings. Also, it is possible to increase wiring density because it is unnecessary to provide a pattern for gold wire connection at a midpoint in a wiring.

The present invention provides a method of manufacturing an wiring substrate which comprises the step of forming on the wiring substrate a first terminal, a second terminal, a first wiring one end of which is connected to the first terminal, a second wiring one end of which is connected to the second terminal, and a plurality of eighth wirings which connect the other end of the first wiring and the other end of the second wiring together, and the step of decoupling at least one of the plurality of eighth wirings.

The present invention provides a method of manufacturing an wiring substrate which comprises the step of forming on the wiring substrate a first terminal, a second terminal, a first wiring which connects the first terminal and the second terminal together, a fifth wiring one end of which is connected to the second terminal or the first wiring, and a plurality of sixth wirings one end of each of which is connected to the other end of the fifth wiring, and the step of decoupling the fifth wiring and the plurality of sixth wirings at least at one point.

According to the present invention, it is possible to increase wiring density and it is possible to adjust the transmission speed of signals without making a design change of wirings.

### BRIEF DESCRIPTION OF THE DRAWINGS

FIG. 1A is an enlarged plan view of the essential part of an wiring substrate in the first embodiment and FIG. 1B is a sectional view of FIG. 1A;

FIG. 2 is a diagram showing a wiring substrate in which a first path is selected as a path of signals from a first wiring to a second wiring;

FIG. 3 is a diagram showing a wiring substrate in which a second path is selected as a path of signals from a first wiring to a second wiring;

FIG. 4 is a diagram showing a wiring substrate in which a third path is selected as a path of signals from a first wiring to a second wiring;

FIG. 5 is a diagram showing an example of the back side of a wiring substrate;

FIG. 6 is a flowchart showing a method of manufacturing a wiring substrate in this embodiment;

FIG. 7 is a sectional view showing an example of a test wiring substrate, a semiconductor chip and a printed circuit board in S120 of FIG. 6;

FIG. 8 is a plan view to explain the configuration of a semiconductor chip;

FIGS. 9A and 9B are a plan view and a sectional view, respectively, to explain S150 of FIG. 6 in detail;

FIGS. 10A and 10B are a plan view and a sectional view, respectively, to explain S150 of FIG. 6 in detail;

FIGS. 11A and 11B are a plan view and a sectional view, respectively, to explain S150 of FIG. 6 in detail;

FIG. 12 is a sectional view of an electronic device in the second embodiment;

FIG. 13 is a plan view of a wiring substrate in the third embodiment;

FIG. 14 is a plan view showing an example of selection of a path from a first wiring to a second wiring in the wiring substrate shown in FIG. 13;

FIG. 15 is a plan view showing another example of selection of a path from a first wiring to a second wiring in the wiring substrate shown in FIG. 13;

FIG. 16 is a plan view of a wiring substrate in the fourth embodiment;

FIG. 17 is a diagram to explain the principle of the fourth embodiment;

FIG. 18 is a plan view showing a first example in which the length of wirings connected to a first wiring is adjusted in the wiring substrate of FIG. 16;

FIG. 19 is a plan view showing a second example in which the length of wirings connected to a first wiring is adjusted in the wiring substrate of FIG. 16;

FIG. 20 is a plan view showing a third example in which the length of wirings connected to a first wiring is adjusted in the wiring substrate of FIG. 16;

FIG. 21 is a plan view of a wiring substrate in the fifth embodiment;

FIG. 22 is a plan view of a wiring substrate in the sixth embodiment;

FIG. 23 is a plan view of an wiring substrate in the seventh embodiment; and

FIG. 24 is a plan view of a wiring substrate in the eighth embodiment.

### DETAILED DESCRIPTION OF THE PREFERRED EMBODIMENTS

Embodiments of the present invention will be described below with reference to the accompanying drawings. Incidentally, in all of the drawings, similar numerals refer to similar component elements and descriptions of such component elements are appropriately omitted.

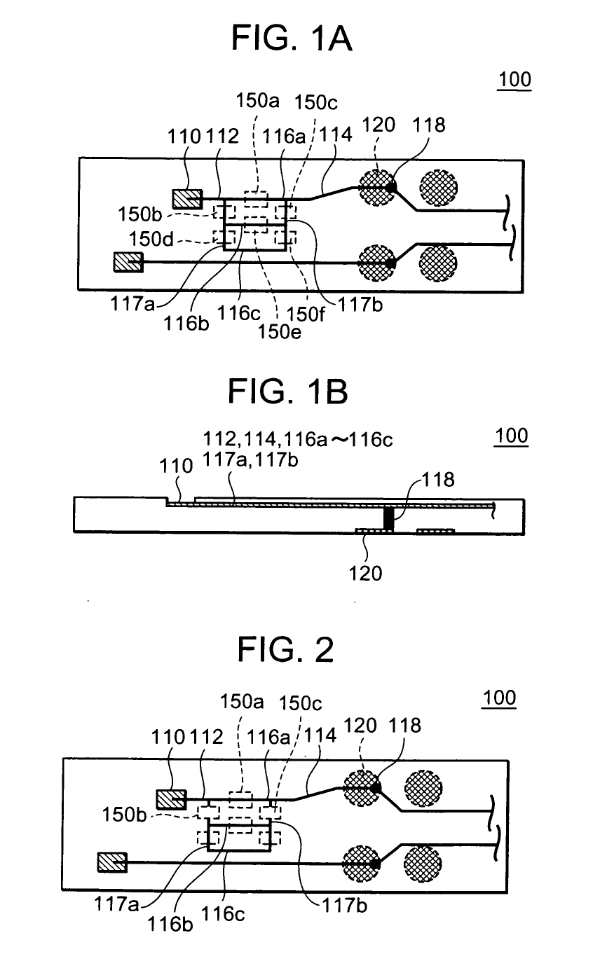

FIG. 1A is an enlarged plan view of the essential part of a wiring substrate 100 in the first embodiment and FIG. 1B is a sectional view of FIG. 1A. The wiring substrate 100 is provided with a first terminal 110, a second terminal 120, a first wiring 112, a second wiring 114, a plurality of third wirings and a plurality of fourth wirings. In the example shown in this figure, the plurality of third wirings and the plurality of fourth wirings are formed by a tenth wiring 117a, an eleventh wiring 117b and twelfth wirings 116a to 116c.

The first terminal 110 is connected to a first electronic part, and the second terminal 120 is connected to a second electronic part. The first wiring 112 is such that one end thereof is connected to the first terminal 110, and the second wiring 114 is such that one end thereof is connected to the second terminal 120. The plurality of third wirings are such that one end of each of which is connected to the other end of the first wiring 112. The plurality of fourth wirings are such that one end of each of which is connected to the other end of the second wiring 114. And the other end of at least one third wiring and the other end of at lest one fourth wiring are connected together. Details of this configuration will be described later with reference to FIGS. 2 to 4. Incidentally, all of the third wirings may be connected to any of the fourth wirings. Although the first electronic part is, for example, a semiconductor chip and the second electronic part is, for example, a mother board or a semiconductor chip, this is not restrictive. Detailed descriptions will be given below.

The wiring substrate 100 is a substrate used in a BGA (ball grid array) or an LGL (land grid array), for example. The first terminal 110 is, for example, a pad formed in a wiring layer which belongs to the top layer of the wiring substrate 100, and the second terminal 120 is, for example, a ball land formed on the back side of the wiring substrate 100. The first wiring 112, the tenth wiring 117a, the eleventh wiring 117b and the twelfth wirings 116a to 116c are formed in the same layer as the first terminal 110. The second wiring 114 is such that one end thereof is positioned in an wiring layer which belongs to the bottom layer of the wiring substrate 100 and the other end thereof is formed in the same layer as the first terminal 110. The second wiring 114 is linked via a through hole 118, for example, from an wiring layer which belongs to the bottom layer to an wiring layer which belongs to the top layer.

The twelfth wirings 116a to 116c are linear and parallel to each other and have the same length. The twelfth wirings 116a to 116c are arranged side by side in this order and the positions of the end portions of these wirings are aligned with each other when the direction of extension of these wirings is the standard. The twelfth wiring 116a connects the other end of the first wiring 112 and the other end of the second wiring 114 with a straight line. The tenth wiring 117a and the eleventh wiring 117b extend in a direction substantially orthogonal to the twelfth wirings 116a to 116c. The tenth wiring 117a mutually connects ends of the twelfth wirings 116a to 116c on one side, and the eleventh wiring 117b mutually connects ends of the twelfth wirings 116a to 116c on the other side.

The following three paths are conceivable as paths of signals from the first wiring 112 to the second wiring 114. The first path is a path in which signals travel through the twelfth wiring 116a. The second path is a path in which signals travel through part of the tenth wiring 117a, the twelfth wiring 116b and part of the eleventh wiring 117b. The third path is a path in which signals travel through the tenth wiring 117a, the twelfth wiring 116c and the eleventh wiring 117b. These three paths have lengths different from each other. For this reason, by making a selection of a path through which signals are caused to travel, it is possible to adjust the time of signal transmission from the first terminal 110 to the second terminal 120.

Paths of signals from the first wiring 112 to the second wiring 114 can be selected by decoupling the tenth wiring 117a, the eleventh wiring 117b and the twelfth wirings 116a to 116c at specific points selected from prescribed decoupling points 150a to 150f. The decoupling point 150a is positioned in the twelfth wiring 116a, and the decoupling point 150e is positioned in the twelfth wiring 116b. The decoupling points 150b and 150c are positioned in portions of the tenth wiring 117a and the eleventh wiring 117b, respectively, between the twelfth wiring 116a and the twelfth wiring 116b. The decoupling points 150d and 150f are positioned in portions of the tenth wiring 117a and the eleventh wiring 117b, respectively, between the twelfth wiring 116b and the twelfth wiring 116c.

FIG. 2 is a diagram showing a wiring substrate in which the first path is selected as a path of signals from the first wiring 112 to the second wiring 114. In the example shown in this figure, the decoupling points 150b and 150c are decoupled among the decoupling points 150a to 150f. As a result of this, signals pass through the first path and do not pass through the second path or the third path. Incidentally, in the example shown in this figure, the twelfth wiring 116a falls under the category of wirings whose ends on the other side are connected to each other among the third wirings and the fourth wirings. The end of the tenth wiring 117a on the side where the tenth wiring 117a is connected to the first wiring 112 falls under the category of wirings among the third wirings which are not connected to the fourth wirings, and the end of the tenth wiring 117a on the side where the tenth wiring 117a is connected to the second wiring 114 falls under the category of wirings among the fourth wirings which are not connected to the third wirings.

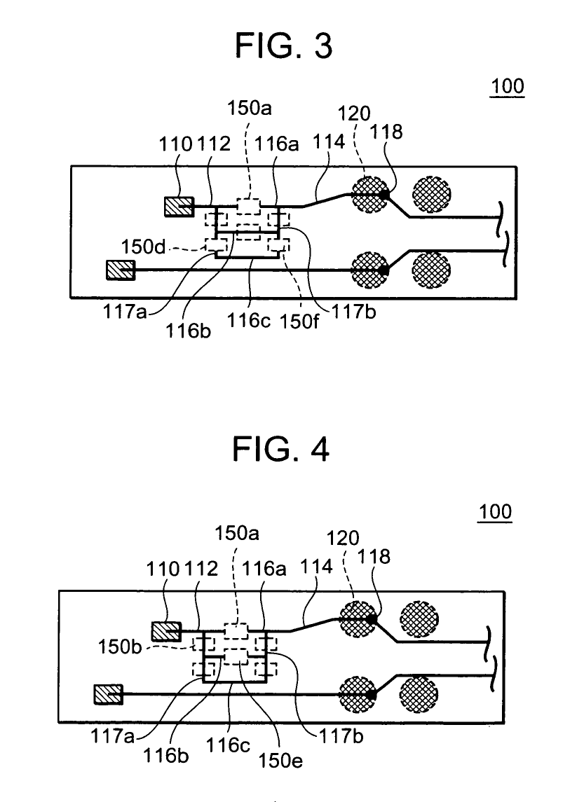

FIG. 3 is a diagram showing a wiring substrate in which the second path is selected as a path of signals from the first wiring 112 to the second wiring 114. In the example shown in this figure, the decoupling points 150a, 150d, 150f are decoupled among the decoupling points 150a to 150f. As a result of this, signals pass through the second path and do not pass through the first path or the third path. Incidentally, in the example shown in this figure, part of the tenth wiring 117a, the twelfth wiring 116a and part of the eleventh wiring 117b fall under the category of wirings whose ends on the other side are connected to each other among the third wirings and the fourth wirings. The side of the twelfth wiring 116a at one end falls under the category of wirings among the third wirings which are not connected to the fourth wirings, and the side of the twelfth wiring 116b at the other end falls under the category of wirings among the fourth wirings which are not connected to the third wirings.

FIG. 4 is a diagram showing a wiring substrate in which the third path is selected as a path of signals from the first wiring 112 to the second wiring 114. In the example shown in this figure, the decoupling points 150a and 150e are decoupled among the decoupling points 150a to 150f. As a result of this, signals pass through the third path and do not pass through the first path or the second path. Incidentally, in the example shown in this figure, the tenth wiring 117a, the twelfth wiring 116a and the eleventh wiring 117b fall under the category of wirings whose ends on the other side are connected to each other among the third wirings and the fourth wirings. The side of the twelfth wiring 116a at one end and the side of the twelfth wiring 116b at the other end fall under the category of wirings among the third wirings which are not connected to the fourth wirings, and the side of the twelfth wiring 116a at one end and the side of the twelfth wiring 116b at the other end fall under the category of wirings among the fourth wirings which are not connected to the third wirings.

Although in the examples shown in FIGS. 2 to 4 only one is selected from the first path to the third path, all of the three of the first path to the third path may also be used in combination without the decoupling of the decoupling points 150a to 150f. Also, two of the first path to the third path may be used in combination. For example, it is possible to use the first path and the second path in combination by decoupling the decoupling points 150d, 150f, it is possible to use the second path and the third path in combination by decoupling the decoupling point 150a, and it is possible to use the first path and the third path in combination by decoupling the decoupling point 150e.

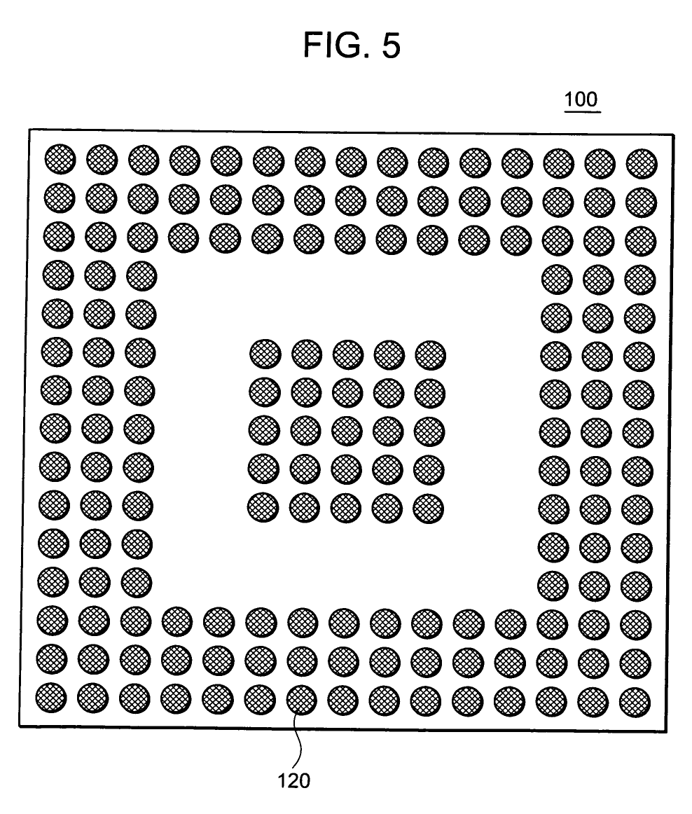

FIG. 5 is a diagram showing an example of the back side of the wiring substrate 100. In this figure, the wiring substrate 100 is substantially square, and the second terminal 120 is horizontally symmetrically arranged in the peripheral part and central part of the back side of the wiring substrate 100. Incidentally, the wiring substrate 100 may also be rectangular and it is not always necessary that the second terminal 120 be horizontally symmetrically arranged.

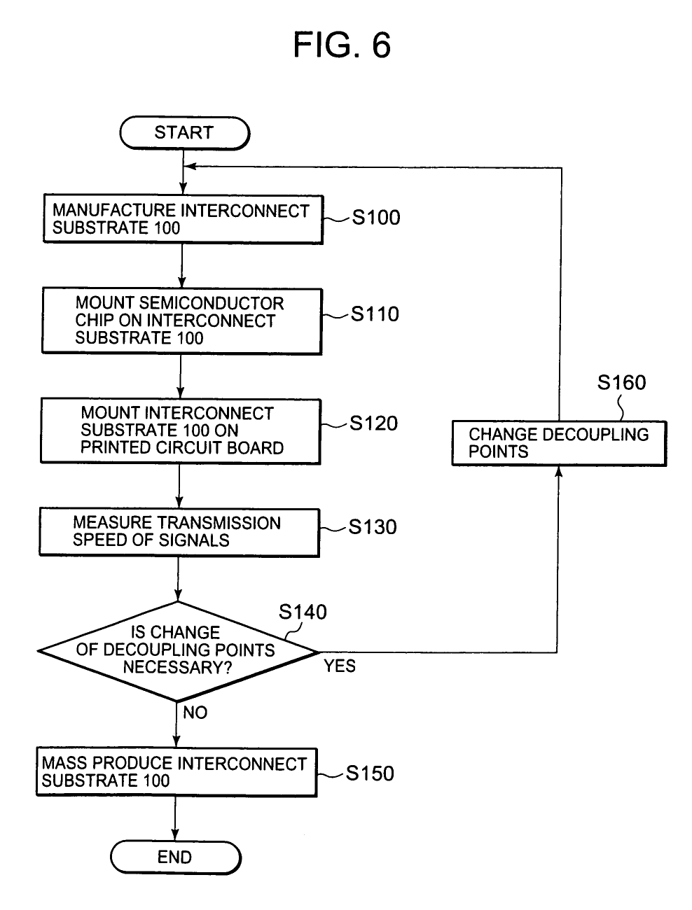

FIG. 6 is a flowchart showing a method of manufacturing the wiring substrate 100 in this embodiment. First, the wiring substrate 100 is fabricated (S100). In this state, the wiring substrate 100 has the structure shown in FIG. 2, FIG. 3 or FIG. 4.

Subsequently, a semiconductor chip as a first electronic part is mounted on the wiring substrate 100 (S110), and the wiring substrate 100 is mounted on a printed circuit board (for example, a mother board) as a second electronic part (S120). Other electronic parts have already been mounted on the printed circuit board. Subsequently, the signal transmission speed between other electronic parts and the semiconductor chip on the printed circuit board is measured (S130), and on the basis of the result of this measurement a judgment is made as to whether or not a change of decoupling points is necessary, that is, whether or not a change of the signal transmission route is necessary (S140). When a change of the signal transmission route is unnecessary (S140: No), the wiring substrate 100 is mass produced without making a change of decoupling points (S150). When a change of the signal transmission route is necessary (S140: Yes), after decoupling points of the wiring substrate 100 are changed (S160), the flow of the manufacturing process returns to S100 and the steps S100 to S160 are repeated until it becomes unnecessary to change decoupling points.

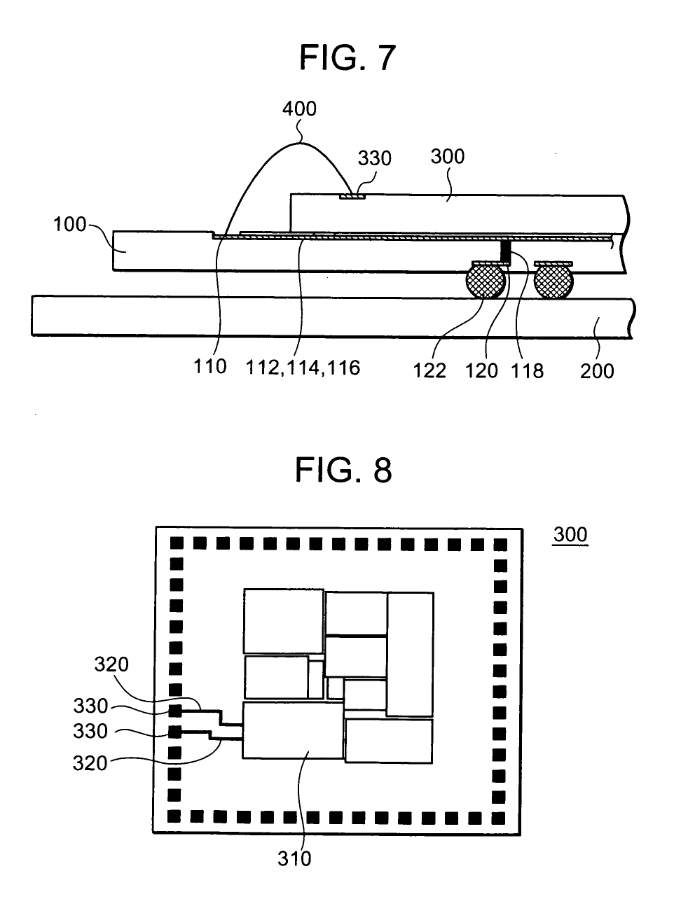

FIG. 7 is a sectional view showing an example of the wiring substrate 100, the semiconductor chip 300 and the printed circuit board 200 in S120 of FIG. 6. In the example shown in this figure, the semiconductor chip 300 is directly mounted on the wiring substrate 100. The first terminal 110 of the wiring substrate 100 is connected to an external connection terminal 330 of the semiconductor chip 300 via a bonding wire 400, and the second terminal 120 is connected to an external connection terminal (not shown) of the printed circuit board 200 via a solder ball 122.

Incidentally, electronic devices using the wiring substrate 100 mass produced in S150 of FIG. 6 have the same configuration as shown in FIG. 7.

FIG. 8 is a plan view to explain the configuration of the semiconductor chip 300. The semiconductor chip 300 is such that the planar shape thereof is substantially square and a plurality of external connection terminals 330 are arranged along the four sides. A plurality of circuits are formed in the middle part of the semiconductor chip 300. These circuits include a circuit 310 for which it is necessary to make the transmission speeds of a plurality of signals equal. The circuit 310 includes at least one selected from the group consisting of, for example, a differential circuit, an I/O circuit of DDR-SDRAM (double-data-rate synchronous dynamic random access memory), USB (universal serial bus), USB2, HDMI (high-definition multimedia interface), SATA (serial advanced technology attachment, serial ATA), DDR2-SDRAM, LVDS (low voltage differential signaling) and the like.

A plurality of in-chip wirings 320 are connected to the circuit 310. The plurality of in-chip wirings 320 are each linked to the external connection terminals 330 which are different from each other. A plurality of signals whose transmission speeds are to be made equal are inputted to the circuit 310 via the plurality of external connection terminals 330 and the plurality of in-chip wirings 320. Conversely, a plurality of signals whose transmission speeds are to be made equal may sometimes be outputted from the circuit 310 via the plurality of external connection terminals 330 and the plurality of in-chip wirings 320.

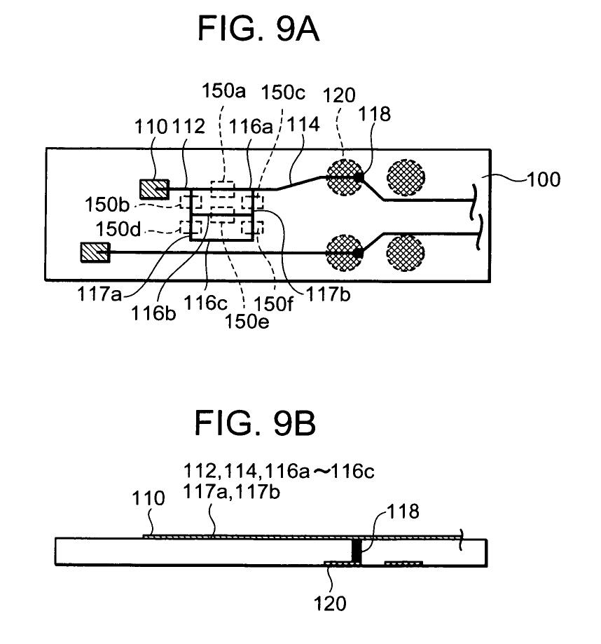

Each of FIGS. 9 to 11 is a diagram to explain S150 of FIG. 6 in detail. First, as shown in the plan view of FIG. 9A and the sectional view of FIG. 9B, the portion of the wiring substrate 100 except a protective film which belongs to the top layer is formed. In this state, the wiring layer which belongs to the top layer is exposed. The wiring layer which belongs to the top layer includes the first terminal 110, the first wiring 112, the side of the second wiring 114 at the other end, the tenth wiring 117a, the eleventh wiring 117b and the twelfth wirings 116a to 116c. In this state, none of the decoupling points 150a to 150f are decoupled. A plurality of groups of third wirings and fourth wirings constitute a plurality of eighth wirings.

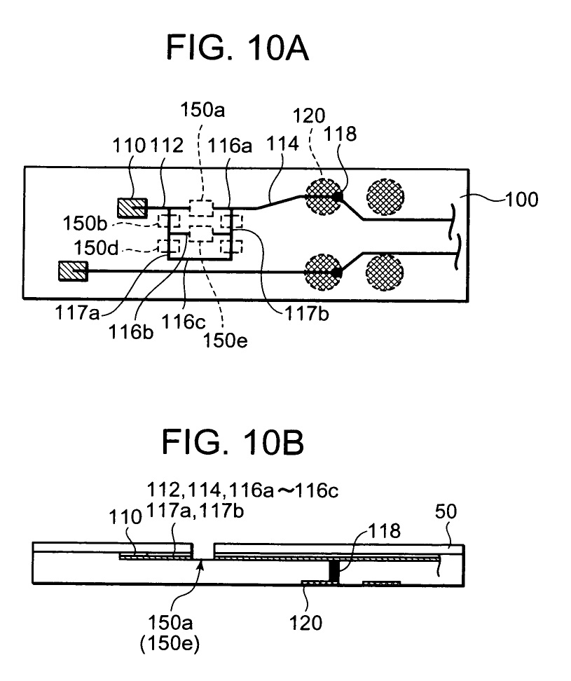

Subsequently, as shown in the plan view of FIG. 10A and the sectional view of FIG. 10B, a protective film (for example, a solder resist) of the wiring substrate 100 is formed and the protective film is selectively removed, whereby the first terminal 110 and portions of the decoupling points of wirings to be decoupled are exposed. Subsequently, a mask pattern 50, such as a resist pattern, is formed on the protective film and on the first terminal 110, and the wiring layer which belongs to the top layer is etched by using the mask pattern 50 as a mask. As a result of this, necessary points among the decoupling points 150a to 150f are decoupled and at least one of the plurality of the eighth wirings is decoupled, with at least one of the plurality of the eighth wirings brought into a non-decoupled condition. The example shown in these figures is a case where the third path shown in FIG. 4 is selected as a path from the first wiring 112 to the second wiring 114, and the decoupling points 150a and 150e are decoupled.

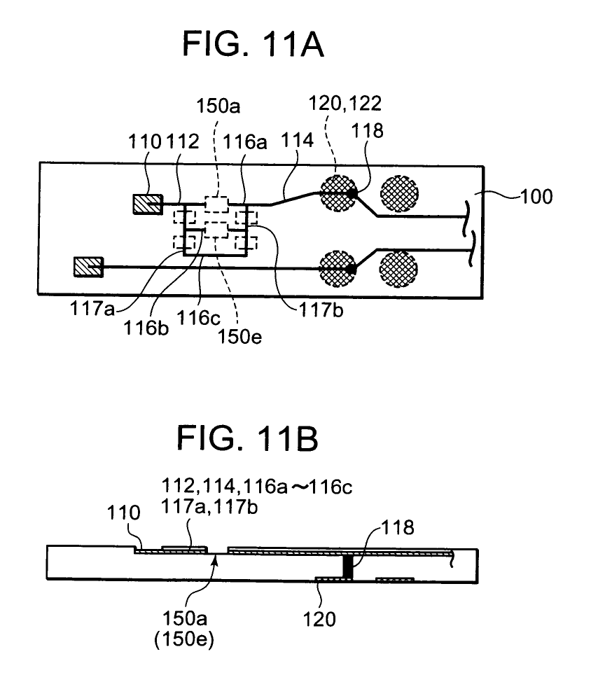

Subsequently, as shown in the plan view of FIG. 11A and the sectional view of FIG. 11B, the mask pattern 50 is removed. The wiring substrate 100 is fabricated in this manner.

Next, the operational advantage of the present invention will be described. In this embodiment, the transmission speed of signals in the wiring substrate 100 is actually measured, and on the basis of the result of this measurement any of the paths shown in FIGS. 2 to 4 is selected as a path from the first wiring 112 to the second wiring 114. And to obtain the selected path, in the manufacturing process of the wiring substrate 100, necessary points among the decoupling points 150a to 150f are decoupled. Therefore, it is possible to adjust the transmission speed of signals without making a design change of the wiring substrate. Also, it is possible to increase wiring density because it is unnecessary to form a pattern for wire connection at a midpoint in a wiring.

After the formation of the first terminal 110, the first wiring 112, the side of the second wiring 114 at the other end, the tenth wiring 117a and the eleventh wiring 117b, the mask pattern 50 is formed and etching is performed, whereby it is possible to easily select any of the paths shown in FIGS. 2 to 4. Although the mask pattern 50 may sometimes be formed several times, the cost of mask pattern formation is held down by mass production and, therefore, it is possible to suppress an increase in the process cost.

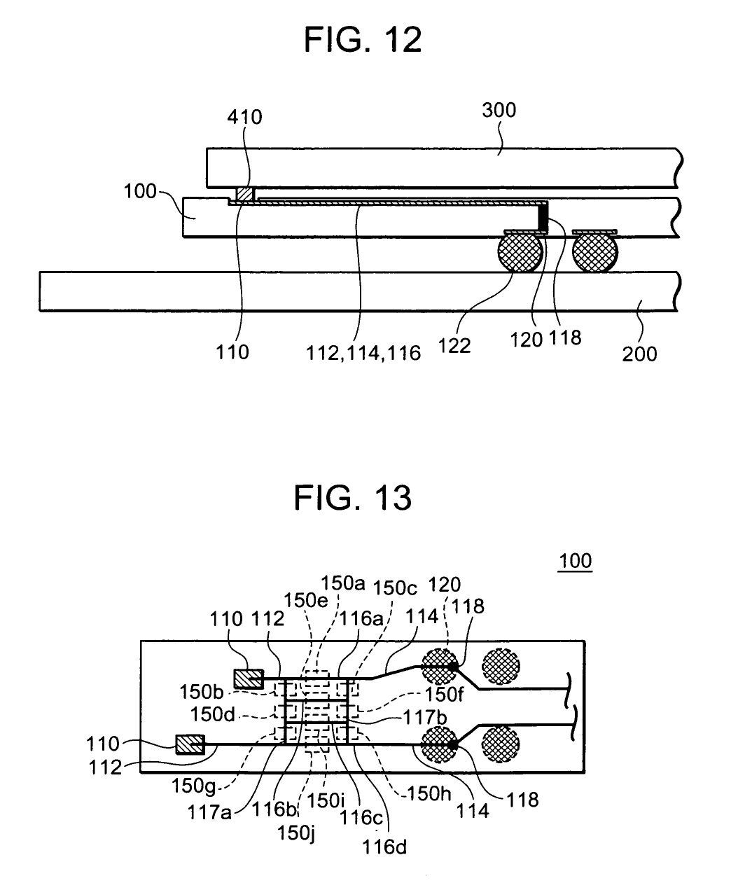

FIG. 12 is a sectional view of an electronic device in the second embodiment. This electronic device has the same configuration as the electronic device described in the first embodiment with reference to FIG. 7, with the exception that the semiconductor chip 300 is flip-chip mounted on a wiring substrate 100 by use of a bump 410. Also the manufacturing method of this electronic device is the same as that of the electronic device described with reference to FIG. 6.

Also from this second embodiment, the same advantage as from the first embodiment can be obtained.

FIG. 13 is a plan view of a wiring substrate 100 in the third embodiment, and this figure corresponds to FIG. 1A in the first embodiment. This third embodiment is the same as the first embodiment with the exception of the following points. A first terminal 110, a first wiring 112, a second wiring 114, a through hole 118 and a second terminal 120 of the first embodiment are all formed in quantities of two in this third embodiment. A tenth wiring 117a short-circuits ends of the two first wirings 112 on the other side, and an eleventh wiring 117b short-circuits ends of the two second wirings 114 on the other side. A plurality of twelfth wirings 116a to 116d short-circuit the tenth wiring 117a and the eleventh wiring 117b at points different from each other. Also in this embodiment, the tenth wiring 117a, the eleventh wiring 117b and the plurality of twelfth wirings 116a to 116d constitute a plurality of third wirings and a plurality of fourth wirings (a plurality of eighth wirings). Incidentally, the twelfth wirings 116d have almost the same length as the twelfth wirings 116a to 116c and are provided substantially parallel to the twelfth wirings 116a to 116c.

In this embodiment, decoupling points 150g to 150j are newly provided in addition to decoupling points 150a to 150f. The decoupling point 150g is provided in a portion of the tenth wiring 117a between the twelfth wiring 116c and the twelfth wiring 116d, and the decoupling point 150h is provided in a portion of the eleventh wiring 117b between the twelfth wiring 116c and the twelfth wiring 116d. The decoupling point 150i is provided in the twelfth wiring 116d. The decoupling point 150j is provided in a portion of the other first wiring 112 between the tenth wiring 117a and the eleventh wiring 117b.

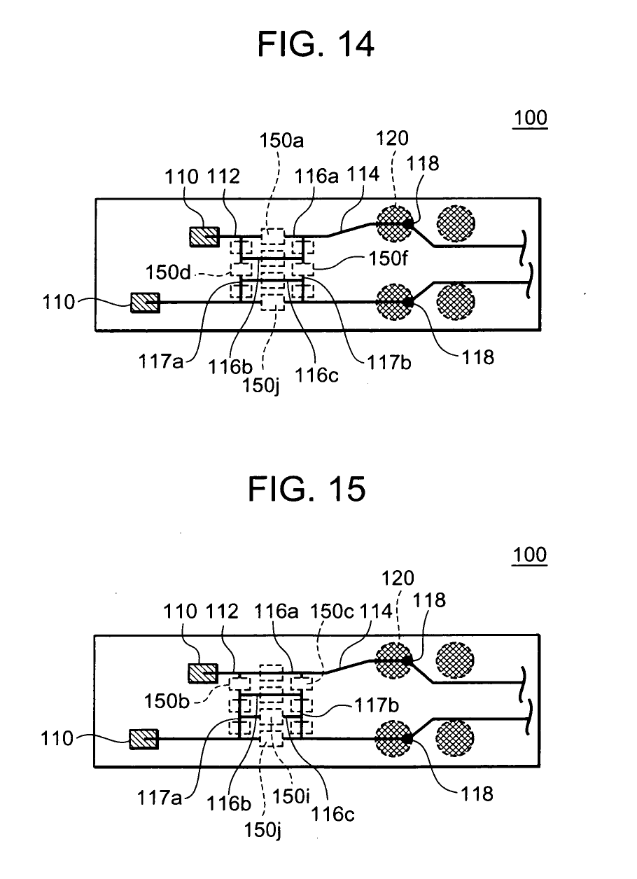

The plan view of FIG. 14 shows an example of selection of a path from the first wiring 112 to the second wiring 114 in the wiring substrate 100 shown in FIG. 13. In this figure, the decoupling points 150a, 150d, 150f, 150j are decoupled, and other decoupling points are not decoupled. In this case, signals which propagate from one first wiring 112 (the first wiring 112 on the upper side of the figure) to one second wiring 114 (the second wiring 114 on the upper side of the figure) pass through part of the tenth wiring 117a, the twelfth wiring 116b and part of the eleventh wiring 117b. Signals which propagate from the other first wiring 112 (the first wiring 112 on the lower side of the figure) to the other second wiring 114 (the second wiring 114 on the lower side of the figure) pass through part of the tenth wiring 117a, the twelfth wiring 116c and part of the eleventh wiring 117b.

FIG. 15 shows another example of selection of a path from the first wiring 112 to the second wiring 114 in the wiring substrate 100 shown in FIG. 13. In this figure, the decoupling points 150b, 150c, 150i, 150j are decoupled, and other decoupling points are not decoupled. In this case, signals which propagate from one first wiring 112 (the first wiring 112 on the upper side of the figure) to one second wiring 114 (the second wiring 114 on the upper side of the figure) pass through the twelfth wiring 116a. Signals which propagate from the other first wiring 112 (the first wiring 112 on the lower side of the figure) to the other second wiring 114 (the second wiring 114 on the lower side of the figure) pass through part of the tenth wiring 117a, the twelfth wiring 116b and part of the eleventh wiring 117b.

Incidentally, in the wiring substrate 100 shown in FIG. 13, the path of signals from the first wiring 112 to the second wiring 114 is not limited to the examples shown in FIGS. 14 and 15, but the decoupling points 150g, 150h, 150i, for example, may also be decoupled.

Also from this embodiment, the same advantage as from the first embodiment can be obtained. Because the two sets of the first wirings 112 and of the second wirings 114 can share the plurality of third wirings and the plurality of fourth wirings (in this embodiment, the tenth wiring 117a, the eleventh wiring 117b and the plurality of twelfth wirings 116a to 116d), the space for the arrangement of the third wirings and the fourth wirings becomes small.

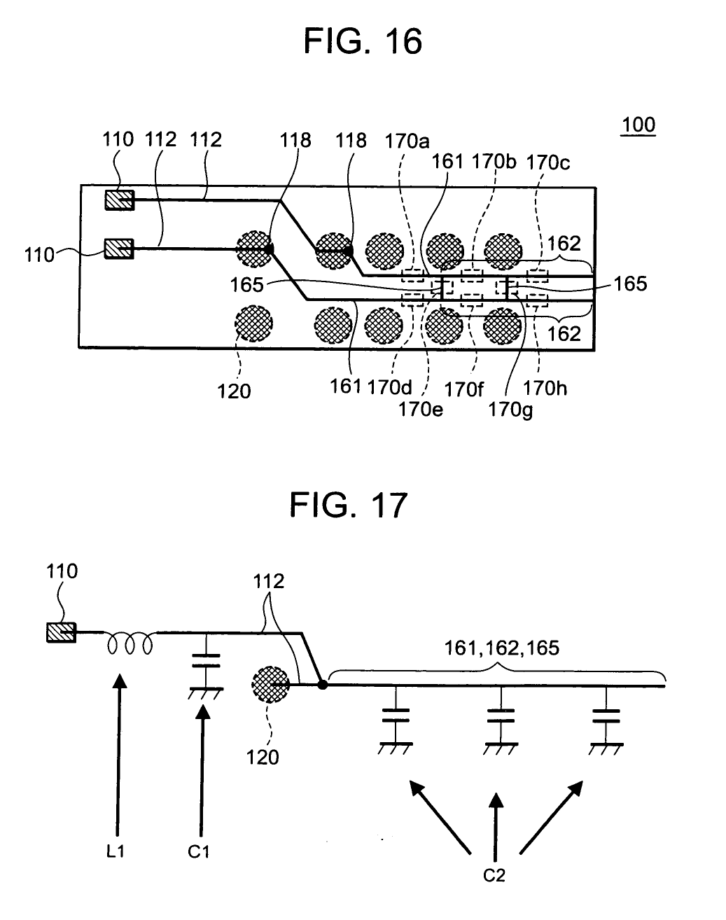

FIG. 16 is a plan view showing the configuration of a wiring substrate 100 in the fourth embodiment. The wiring substrate 100 in this embodiment is provided with a first terminal 110, a first wiring 112, a plurality of fifth wirings 161, a plurality of wirings 162 and a plurality of wirings 165. The wiring substrate 100 in this embodiment adjusts the transmission speed of signals which propagate through the first wiring 112 by changing the length, i.e., capacity of wirings which are electrically connected to the first wiring 112. This principle will be described in detail later.

The configuration of the first terminal 110 is the same as in the first embodiment. In this fourth embodiment, the first wiring 112 extends to the back side of the wiring substrate 100 via a through hole 118 and is connected to a second terminal 120. The configuration of the second terminal 120 is the same as in the first embodiment. The fifth wiring 161 is such that one end thereof is connected to the second terminal 120 or the first wiring 112. In the example shown in this figure, one end of the fifth wiring 161 is connected to the first wiring 112. The wiring 162 is such that one end thereof is connected to the other end of the fifth wiring 161 and the other end thereof extends to an edge of the wiring substrate 100. The fifth wiring 161 and the wiring 162 are used as power supply lines when, for example, the first wiring 112 is formed by the plating method. The wiring 165 mutually short-circuits the plurality of wirings 162. In this embodiment, the wirings 165 closest to the wirings 162 and the fifth wirings 161 constitute a plurality of sixth wirings. The remaining wirings (seventh wirings) mutually short-circuit the plurality of sixth wirings.

The wiring substrate 100 is provided with the first terminals 110 in quantities of two. The first wiring 112, the through hole 118, the fifth wiring 161 and the wiring 162 are provided for each of the two first terminals 110. In this embodiment, the wiring 165 is provided in quantities of two.

In this embodiment, the fifth wirings 161, the wirings 162 and the wirings 165 are provided with a plurality of decoupling points 170a to 170h. The decoupling point 170a is provided in one fifth wiring 161 (for example, the fifth wiring 161 on the upper side of the figure). The decoupling point 170b is positioned in one wiring 162 (for example, the wiring 162 on the upper side of the figure) between the two wirings 165. The decoupling point 170c is positioned in one wiring 162 and is closer to the edge of the wiring substrate 100 than any of the two wirings 165. The decoupling point 170d is provided in the other fifth wiring 161 (for example, the fifth wiring 161 on the lower side of the figure). The decoupling point 170e is provided in one wiring 165. The decoupling point 170f is positioned in the other wiring 162 (for example, the wiring 162 on the lower side of the figure) between the two wirings 165. The decoupling point 170g is provided in the other wiring 165. The decoupling point 170h is positioned in one wiring 162 and is closer to the edge of the wiring substrate 100 than any of the two wirings 165.

FIG. 17 is a diagram to explain the principle of this fourth embodiment, i.e., the reason why the transmission speed of signals which propagate through the first wiring 112 can be adjusted by changing the length, i.e., capacity of wirings which are electrically connected to the first wiring 112. The speed T of a signal which propagates through a wiring can be approximated so as to be proportional to √(LC). Here, L is the inductance of the wiring and C is the capacity of the wiring. If the capacity of the first wiring 112 is denoted by C1, the inductance of the first wiring 112 is denoted by L1, and the total value of the fifth wiring 161 and the wirings 162, 165 is denoted by C2, then the speed T1 of a signal which propagates through the first wiring 112 is proportional to √(LC×(C1+C2)). For this reason, it is possible to adjust the transmission speed of signals which propagate through the first wiring 112 by changing the length of the fifth wiring 161 and the wirings 162, 165, thereby changing the total value C2 of the capacity.

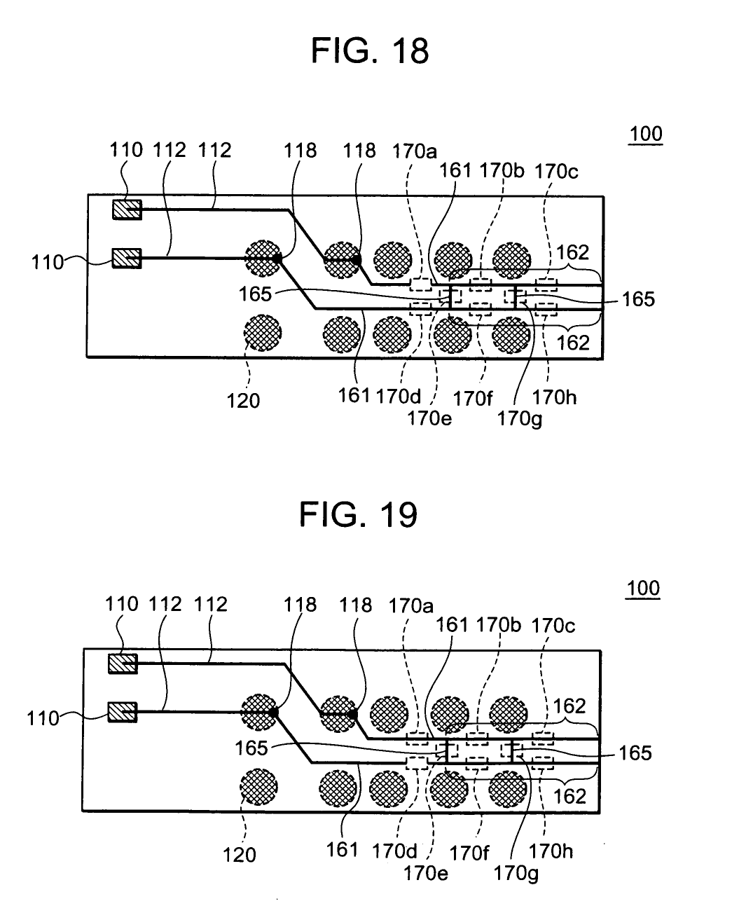

The plan view of FIG. 18 shows a first example in which the length of wirings connected to the first wiring 112 is adjusted in the wiring substrate of FIG. 16. In this figure, the decoupling point 170a is decoupled, but other decoupling points are not decoupled. In this case, compared to a case where the wiring 165 is not provided, the wiring connected to the first wiring 112 on the upper side of the figure becomes short and the capacity of this wiring decreases. On the other hand, the wiring connected to the first wiring 112 on the lower side of the figure becomes long and the capacity of this wiring increases.

The plan view of FIG. 19 shows a second example in which the length of wirings connected to the first wiring 112 is adjusted in the wiring substrate of FIG. 16. In this figure, the decoupling point 170d is decoupled, but other decoupling points are not decoupled. In this case, compared to a case where the wiring 165 is not provided, the wiring connected to the first wiring 112 on the upper side of the figure becomes long and the capacity of this wiring increases. On the other hand, the wiring connected to the first wiring 112 on the lower side of the figure becomes short and the capacity of this wiring decreases.

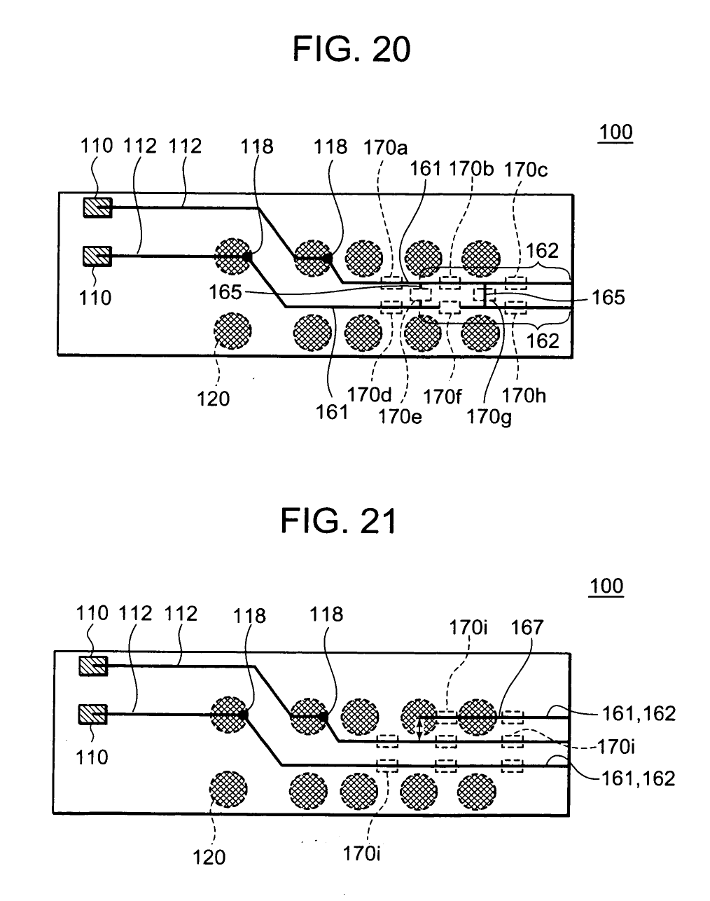

The plan view of FIG. 20 shows a third example in which the length of wirings connected to the first wiring 112 is adjusted in the wiring substrate of FIG. 16. In this figure, the decoupling points 170e, 170f are decoupled, but other decoupling points are not decoupled. In this case, compared to a case where the wiring 165 is not provided, the wiring connected to the first wiring 112 on the upper side of the figure becomes long and the capacity of the wiring connected to this first wiring 112 increases. However, the amount of this change is small compared to the case described in FIG. 19. On the other hand, the wiring connected to the first wiring 112 on the lower side of the figure becomes short and the capacity of the wiring connected to this wiring 112 decreases. However, the amount of this change is small compared to the case described in FIG. 19.

Incidentally, in the wiring substrate of FIG. 16, it is possible to set lengths other than those shown in FIGS. 18, 19 and 20 as the length of the wirings connected to the first wiring 112. For example, if the decoupling points 170e, 170g are decoupled, almost the same length as in the case where the wiring 165 is not provided is obtained. Furthermore, the decoupling points 170e, 170f may be decoupled, and the decoupling points 170e, 170f, 170h may also be decoupled.

Incidentally, the determination of decoupling points is performed in the same manner as the method described in the first embodiment on the basis of FIG. 6.

Also the manufacturing method of a wiring substrate (including the method of determining decoupling points and the decoupling method of decoupling points) in this fourth embodiment and the manufacturing method of an electronic device using this wiring substrate are the same as in the first embodiment. Also from this fourth embodiment, it is possible to obtain the same advantage as from the first embodiment by adjusting the capacity of wirings connected to the first wiring 112.

FIG. 21 is a plan view of a wiring substrate 100 in the fifth embodiment. This wiring substrate 100 is the same as in the fourth embodiment, with the exception that a wiring 167 is provided in place of the wiring 165. The wiring 167 is an example of a sixth wiring, and is such that one end thereof is connected to any of fifth wirings 161 and the other end thereof is positioned at an end of the wiring substrate 100. In this embodiment, each of the fifth wiring 161, the wiring 162 and the wiring 167 is provided with at least one decoupling point 170i.

Incidentally, in the example shown in this figure, the wiring 167 is provided only for one fifth wiring 161 and one wiring 162. However, the wiring 167 may be provided also for the other fifth wiring 161 and the other wiring 162.

Also from this fifth embodiment, it is possible to obtain the same advantage as from the fourth embodiment. Furthermore, because the wiring 167 is connected to the fifth wiring 161 and the wiring 162, it is possible to adjust the capacity of the plurality of fifth wirings 161 and the plurality of wirings 162 independently from each other.

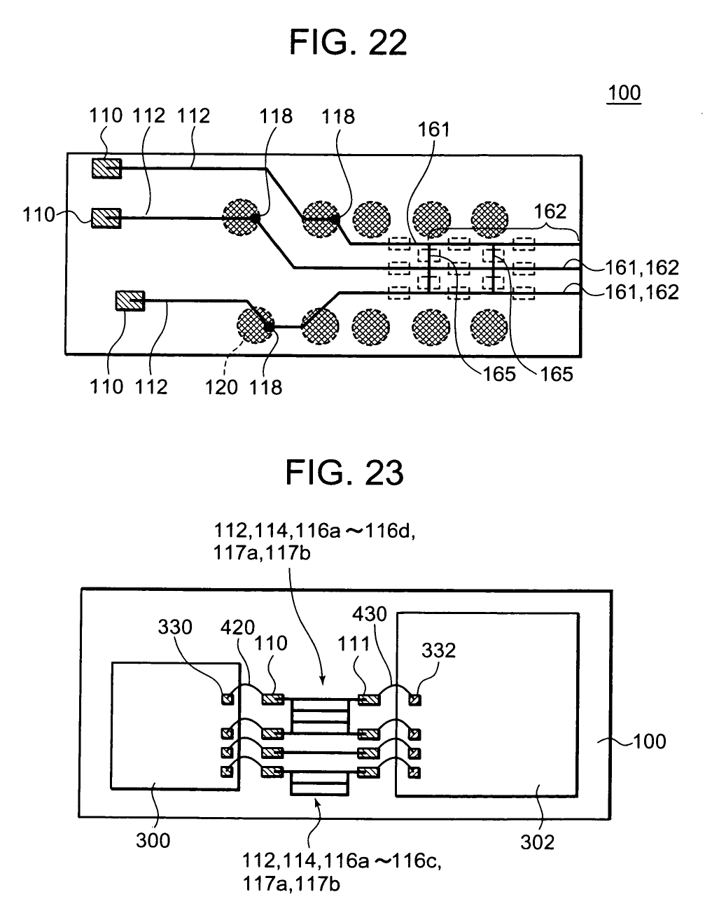

FIG. 22 is a plan view of a wiring substrate 100 in the sixth embodiment. This embodiment is the same as the fourth embodiment, with the exception that a first terminal 110, a first wiring 112, a through hole 118, a fifth wiring 161 and an wiring 162 are provided in three sets, that the two wirings 165 mutually short-circuit the three wirings 162, and that the number of decoupling points increases accordingly. The decoupling points are arranged by the same rule as in the fourth embodiment, and are provided before and behind the areas where the wirings are connected together.

Also from this sixth embodiment, it is possible to obtain the same advantage as from the fourth embodiment. Furthermore, it is possible to more finely adjust the capacity of the wirings connected to the first wiring 112 than in the case of the fourth embodiment.

FIG. 23 is a plan view of an electronic part in the seventh embodiment. This electronic part is such that semiconductor chips 300, 302 are mounted on one surface of a wiring substrate 100. The semiconductor chips 300, 302 are connected to each other via the wiring substrate 100.

The wiring substrate 100 has, on one surface thereof, a plurality of first terminals 110 and a plurality of second terminals 111. The first terminals 110 and the second terminals 111 are all pads. At least two first terminals 110 are connected to the second terminals 111 which are different from each other via the first wirings 112, the second wirings 114, the tenth wirings 117a, the eleventh wirings 117b and the twelfth wirings 116a to 116d shown in the third embodiment. It is necessary to make equal the transmission speeds of signals which flow through at least two first terminals 110.

The first terminal 110 is connected to an external connection terminal 330 of the semiconductor chip 300 via a bonding wire 420, and the second terminal 111 is connected to an external connection terminal 332 of the semiconductor chip 302 via a bonding wire 430. Incidentally, the semiconductor chips 300, 302 may also be flip-chip mounted on the wiring substrate 100.

Also in this seventh embodiment, as described in the first embodiment with reference to FIG. 6, the semiconductor chips 300, 302 are mounted on the wiring substrate 100, the transmission speed of signals is actually measured, and on the basis of the result of this actual measurement the decision is made as to which part of the tenth wiring 117a, the eleventh wiring 117 and the twelfth wirings 116a to 116d is to be decoupled, whereby it is possible to adjust the transmission speed of signals. Therefore, also from this seventh embodiment, it is possible to obtain the same advantage as from the first embodiment.

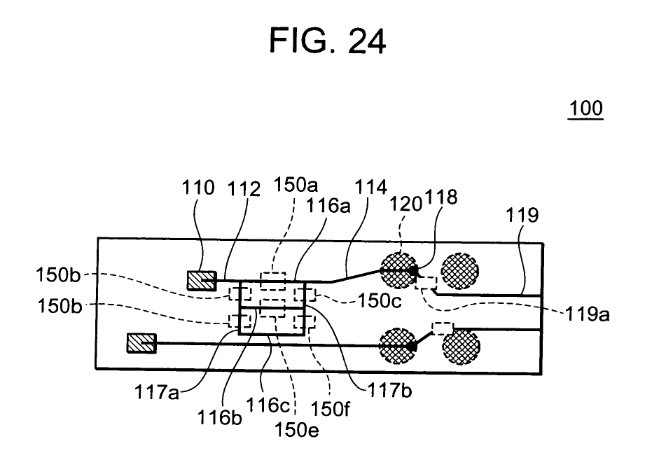

FIG. 24 is a plan view of a wiring substrate 100 in the eighth embodiment. The wiring substrate in this embodiment has the same configuration as the wiring substrate 100 in the first embodiment, with the exception that one end of a plated wire 119 (a ninth wiring) is connected to a second wiring 114, and that the plated wire 119 is decoupled at a decoupling point 119a. The plated wire 119 is such that one end thereof is connected to a portion of the second wiring 114 which enters a through hole 118 and the other end thereof extends to an edge of the wiring substrate 100. The plated wire 119 is formed in the same manufacturing step as for the first wiring 112, the second wiring 114 and the like. The decoupling of the plated wire 119 at the decoupling point 119a is performed in the same manufacturing step as for the decoupling at any of the decoupling points 150a to 150f. Incidentally, it is preferred that the decoupling point 119a be positioned at one end of the plated wire 119, i.e., in a portion where the plated wire 119 is connected to the second wiring 114.

Also from this eighth embodiment, it is possible to obtain the same advantage as from the first embodiment. Furthermore, because the plated wire 119 is decoupled at a midpoint, the antenna effect by the plated wire 119 is suppressed. For this reason, the plated wire 119 is substantially prevented from catching electromagnetic waves from outside and generating noise. When the decoupling point 119a is positioned in a portion of the plated wire 119 connected to the second wiring 114, the wiring connected to the second wiring 114 has no open end and, therefore, signals are prevented from being reflected at an open end even when signals flow through the second wiring 114 at high speeds.

Although the embodiments of the present invention were described above with reference to the drawings, these are illustrations of the invention and it is also possible to adopt various configurations other than those described above. For example, although in each of the above-described embodiments wirings to be decoupled are arranged in an wiring layer which belongs to the top layer, these wirings may also be arranged in other wiring layers (for example, the bottom layer).

What is claimed is:

1. A wiring substrate, comprising:
a first terminal;
a second terminal;
a first wiring one end of which is connected to the first terminal and which is formed on the wiring substrate; and
a second wiring one end of which is connected to the second terminal and which is formed on the wiring substrate,
wherein one end of each of a plurality of third wirings formed on the wiring substrate is connected to the other end of the first wiring, one end of each of a plurality of fourth wirings formed on the wiring substrate is connected to the other end of the second wiring, and the other end of at least one third wiring and the other end of at least one fourth wiring are connected together.

2. The wiring substrate according to claim 1 further comprising:
a ninth wiring one end of which is connected to the first wiring or the second wiring and the other end of which extends to an edge of the wiring substrate,
wherein the ninth wiring is decoupled at a midpoint.

3. A wiring substrate, comprising:
a first terminal;
a second terminal;
a first wiring which connects the first terminal and the second terminal together and is formed on the wiring substrate;
a fifth wiring one end of which is connected to the second terminal or the first wiring and which is formed on the wiring substrate; and
a plurality of sixth wirings one end of each of which is connected to the other end of the fifth wiring and the other end of each of which extends to an edge of the wiring substrate.

4. The wiring substrate according to claim 3, wherein the fifth wiring and the plurality of sixth wirings are decoupled at least at one point.

5. The wiring substrate according to claim 3, further comprising a seventh wiring which short-circuits at least two sixth wirings.

6. A method of manufacturing a wiring substrate, comprising the steps of:
forming on the wiring substrate a first terminal, a second terminal, a first wiring one end of which is connected to the first terminal, a second wiring one end of which is connected to the second terminal, and a plurality of eighth wirings which connect the other end of the first wiring and the other end of the second wiring together; and
decoupling at least one of the plurality of eighth wirings.

7. The method of manufacturing an wiring substrate according to claim 6, further comprising, before the step of forming the first terminal, the second terminal, the first wiring, the second wiring and the plurality of eighth wirings, the steps of:
forming a test wiring substrate having the first terminal, the second terminal, the first wiring, the second wiring and the plurality of eighth wirings;
connecting the first terminal to a first electronic part and connecting the second terminal to a second electronic part;
measuring transmission speed of a signal propagating through the first wiring; and
determining which of the plurality of eighth wirings is to be decoupled on the basis of the transmission speed.

8. The method of manufacturing an wiring substrate according to claim 6, wherein in the step of forming the first terminal, the second terminal, the first wiring, the second wiring and the plurality of eighth wirings, a ninth wiring one end of which is connected to the first wiring or the second wiring and the other end of which extends to an edge of the wiring substrate is formed, and in the step of decoupling at least one of the plurality of eighth wirings, the ninth wiring is decoupled.

9. A method of manufacturing a wiring substrate, comprising:
forming on the wiring substrate a first terminal, a second terminal, a first wiring which connects the first terminal and the second terminal together, a fifth wiring one end of which is connected to the second terminal or the first wiring, and a plurality of sixth wirings one end of each of which is connected to the other end of the fifth wiring; and
decoupling the fifth wiring and the plurality of sixth wirings at least at one point.

10. The method of manufacturing a wiring substrate according to claim 9, wherein forming the plurality of sixth wirings includes causing the other end of each of the plurality of sixth wirings to extend to an edge of the wiring substrate.

11. The method of manufacturing an wiring substrate according to claim 9, further comprising, before forming the first terminal, the second terminal, the first wiring, the fifth wiring and the plurality of sixth wirings:
forming a test wiring substrate having the first terminal, the second terminal, the first wiring, the fifth wiring and the plurality of sixth wirings;
connecting the first terminal to a first electronic part and connecting the second terminal to a second electronic terminal;
measuring delay time of a signal propagating through the first wiring; and
determining decoupling points of the fifth wiring and the plurality of sixth wirings on the basis of the delay time.
